(19) United States
(12) Patent Application Publication
(10) Pub. No.: US 2012/0291706 A1
(43) Pub. Date: Nov. 22, 2012

(54) Atmospheric Pressure Plasma Processing Apparatus

(75) Inventors: Hiroyuki KOBAYASHI, Kodaira (JP); Hiroaki KAKIUCHI, Suita (JP); Kiyoshi YASUTAKE, Suita (JP)

(73) Assignee: Hitachi, Ltd., Tokyo (JP)

(21) Appl. No.: 13/464,427

(22) Filed: May 4, 2012

(30) Foreign Application Priority Data
May 17, 2011 (JP) 2011-110512

(51) Int. Cl. C23C 16/50

(52) U.S. Cl. 118/723 E

(57) ABSTRACT

In a plasma source of a plasma processing apparatus, the plasma source being of the dielectric barrier discharge mode of an surface discharge type, incorporating electrodes in pairs (an antenna, and a ground) areally formed inside a dielectric, a subject under-processing is kept substantially in contact with the plasma source, thereby causing a plasma to be generated on a plane on a side of the subject under-processing, opposite from a plane on which the plasma source is provided.

### CLAIM OF PRIORITY

The present application claims priority from Japanese patent application JP 2011-110512 filed on May 17, 2011, the content of which is hereby incorporated by reference into this application.

### FIELD OF THE INVENTION

The present invention relates to an atmospheric pressure plasma processing apparatus for carrying out film-formation, surface modification, sterilization, and so forth by use of an atmospheric pressure plasma, and a plasma processing method using the atmospheric pressure plasma processing apparatus.

### BACKGROUND OF THE INVENTION

As progress has lately been made in studies on a technology for plasma generation at an atmospheric-pressure, so generation of a functional film such as a Si-based thin film, a diamond-like carbon (DLC) thin film, and so forth, removal of an organic substance from the surface of material, and plasma sterilization have come to be extensively studied. In the atmospheric pressure plasma processing, if plasma processing is applied to a subject under-processing, not less than a given size in area (for example, a substrate of 1 m×1 m in area), the dielectric barrier discharge mode has been in widespread use. Broadly speaking, the dielectric barrier discharge mode includes two modes. One of the modes is, for example, a mode using remote plasma, as described in, Patent Document 1, whereby a plasma is generated from a plasma source of a parallel flat-plate type with an dielectric inserted between two metal sheets disposed in parallel. The other is, for example, an surface discharge mode, as described in Japanese Unexamined Patent Application Publication No. 2006-331664, whereby comb-shaped electrodes in pairs are disposed in one dielectric plane. A discharge electrode pattern according to this surface discharge mode has been adopted for the plasma display panel from the past.

### SUMMARY OF THE INVENTION

For the atmospheric pressure plasma processing apparatus for use in film-formation, and so forth, use is mainly made of the barrier discharge mode of the parallel flat-plate type, as described in, for example, US Patent Application Publication No. US2007/0123041A1. In the case of the dielectric barrier discharge mode of the parallel flat-plate type, a plasma is generated between two sheets of discharge electrodes, and a subject under-processing is inserted between, for example, the discharge electrodes, or the subject under-processing is disposed in the vicinity below the discharge electrode, thereby carrying out a processing for film-formation. As a problem with this mode, there is cited film-formation occurring on the surface of the discharge electrode, serving as the plasma source, as well, besides on the surface of the subject under-processing. The film adhered to the discharge electrode peels off as a foreign matter, thereby interfering with the processing for film-formation. For this reason, if there occurs adhesion of the film in excess of a given thickness, this will require replacement of the discharge electrode, and cleaning thereof, thereby causing deterioration in availability of the system, and impairment in productivity on a mass production basis.

Meanwhile, with the plasma processing apparatus based on the surface discharge mode described in Japanese Unexamined Patent Application Publication No. 2006-331664, parallelly arranged linear electrodes for generating a plasma are embedded in an dielectric, and a plane in which the linear electrodes are arranged is disposed so as to be opposed to a processing plane (surface) of a subject under-processing with a gap of, for example, 2 mm, provided therebetween, thereby transferring the subject under-processing by use of a transfer unit.

As a problem with this mode as well, there is also cited film-formation occurring on the surface of the plasma source, as well, besides on the surface of the subject under-processing as is the case with the dielectric barrier discharge mode of the parallel flat-plate type.

It is therefore an object of the invention to provide an atmospheric pressure plasma processing apparatus for use in forming a film primarily on a subject under-processing, the system being capable of inhibiting film-formation at a site other than the subject under-processing, and a plasma processing method using the atmospheric pressure plasma processing apparatus.

A representative aspect of the invention is described as follows. More specifically, a plasma processing apparatus according to the invention includes a plasma discharge unit in an ambient atmosphere, installed inside a processing chamber, a high-frequency power source for supplying high-frequency power to the plasma discharge unit, a processing gas supply source for supplying a processing gas to the processing chamber, and a subject under-processing holding unit for holding the back surface of a subject under-processing. The plasma discharge unit is a plasma source of the dielectric barrier discharge mode of an surface discharge type, incorporating electrodes in pairs, disposed in parallel with each other inside a dielectric, thereby generating a plasma on a surface of the dielectric, the subject under-processing is held by a predetermined subject under-processing holding plane in the plasma discharge unit, the surface of the dielectric, and the subject under-processing holding plane are effectively at the same level in the plasma discharge unit, thereby enabling the plasma to be generated in the ambient atmosphere in the vicinity of a surface of the subject under-processing, on a side thereof, opposite from the subject under-processing holding plane.

According to the aspect of the invention, because a plasma is generated only in the vicinity of the surface of the subject under-processing, it is possible to inhibit film-formation on the plasma discharge unit, and the inner wall of a processing vessel, so that a cleaning cycle of the plasma processing apparatus can be prolonged, and productivity on a mass production basis can be enhanced.

### BRIEF DESCRIPTION OF THE DRAWINGS

FIG. 1 is a schematic representation showing a general configuration of an atmospheric pressure plasma processing apparatus according to a first embodiment of the invention;

FIG. 2A is a schematic illustration showing a sectional structure of a plasma discharge unit according to the first embodiment, and a positional relationship among the plasma discharge unit, a subject under-processing, and a plasma;

FIG. 2B is a schematic illustration showing an operation in the case where no gap exists in the plasma discharge unit according to the first embodiment;

FIG. 2C is a schematic illustration showing an operation of the plasma discharge unit in the case where a gap exists in the plasma discharge unit according to the first embodiment;

FIG. 3 is a schematic sectional view (taken on line A-A′ of FIG. 2A) of the discharge unit according to the first embodiment;

FIG. 4 is a schematic representation showing a construction of a gas-atmosphere change-over device;

FIG. 5 is a schematic representation showing a general configuration of an atmospheric pressure plasma processing apparatus according to a second embodiment of the invention;

FIG. 6 is a schematic representation showing an electrode structure of a cylindrical plasma-discharge unit according to the second embodiment;

FIG. 7A is a schematic representation showing an electrode structure of another cylindrical plasma-discharge unit according to a first modification of the second embodiment of the invention;

FIG. 7B is an enlarged sectional view showing the construction of a part R of FIG. 7A by way of example;

FIG. 8 is a schematic representation showing a general configuration of an atmospheric pressure plasma processing apparatus according to a third embodiment of the invention;

FIG. 9 is a schematic representation showing an electrode structure of a cylindrical plasma-discharge unit according to the third embodiment;

FIG. 10A is a schematic representation showing an electrode structure of a cylindrical plasma-discharge unit according to a second modification of the third embodiment; and

FIG. 10B is an enlarged sectional view showing the construction of a part P of FIG. 10A by way of example.

### DETAILED DESCRIPTION OF THE PREFERRED EMBODIMENTS

A plasma processing apparatus according to the invention includes a plasma discharge plate of the dielectric barrier discharge mode of an surface discharge type, incorporating electrodes in pairs (an antenna, and a ground) areally formed inside one dielectric, the back surface of a subject under-processing being brought into intimate contact with the plasma discharge plate in an ambient atmosphere, and a plasma is generated on the surface of the subject under-processing, on a side thereof, opposite from the plasma discharge plate, thereby executing a processing for film-formation. Further, for a processing gas for use in the film-formation, use is made of a processing gas diluted by a rare gas having a tendency toward electric discharge, such as helium, argon, and so forth, and the processing gas is supplied to a portion of space, adjacent to plasma generation while a gas, such as, for example, nitrogen more resistant to electric discharge than the processing gas, is supplied as necessary to a portion of the space, between the back surface of the subject under-processing, and the discharge plate, thereby causing inhibition of electric discharge in a miniscule gap between the discharge plate, and the back surface of the subject under-processing. In the present invention, an ambient atmosphere indicates that the pressure of the processing gas is equivalent to that of the atmosphere.

There are described hereinafter specific embodiments of a plasma processing apparatus according to the invention, and a plasma processing method according to the invention, respectively, with reference to the accompanying drawings.

### First Embodiment

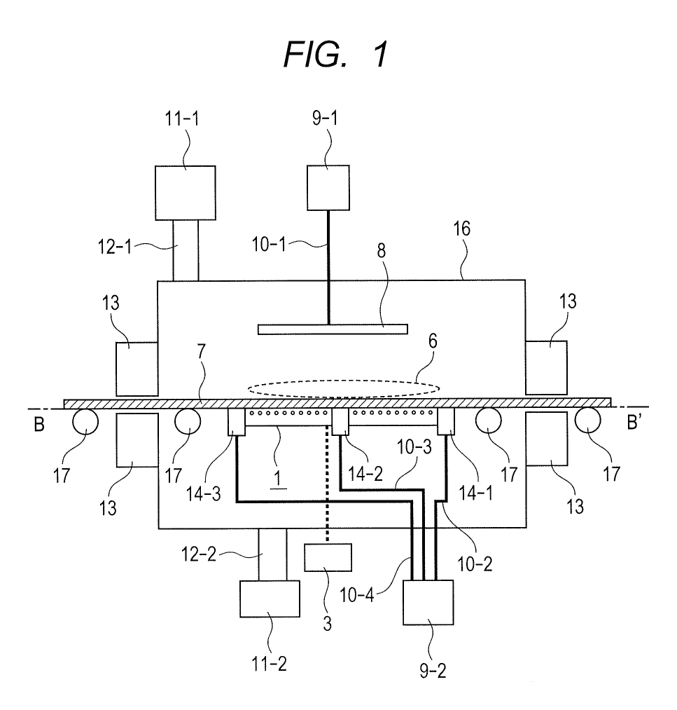

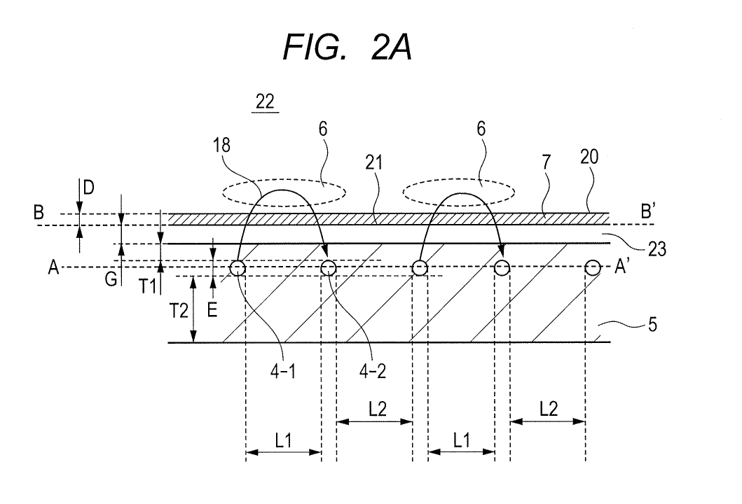

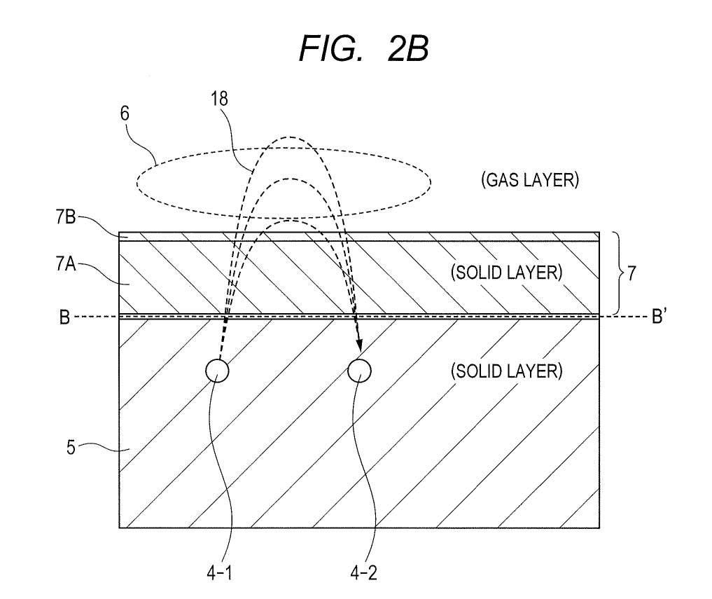

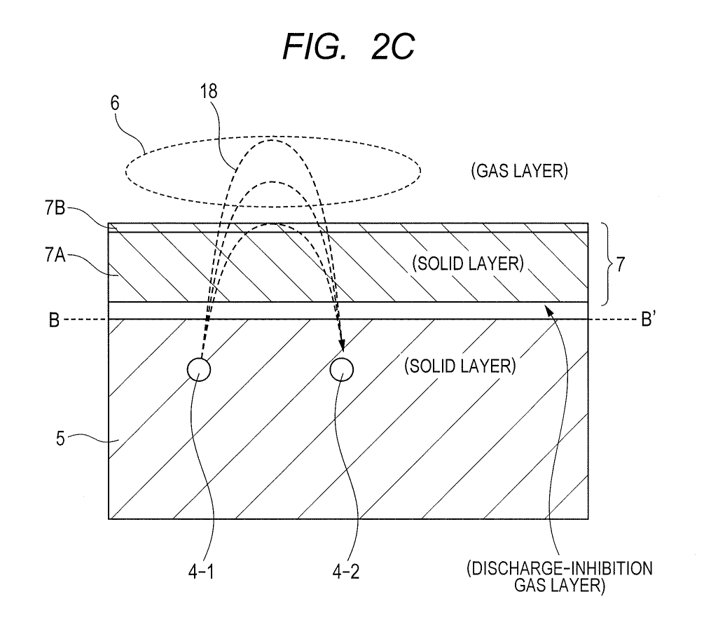

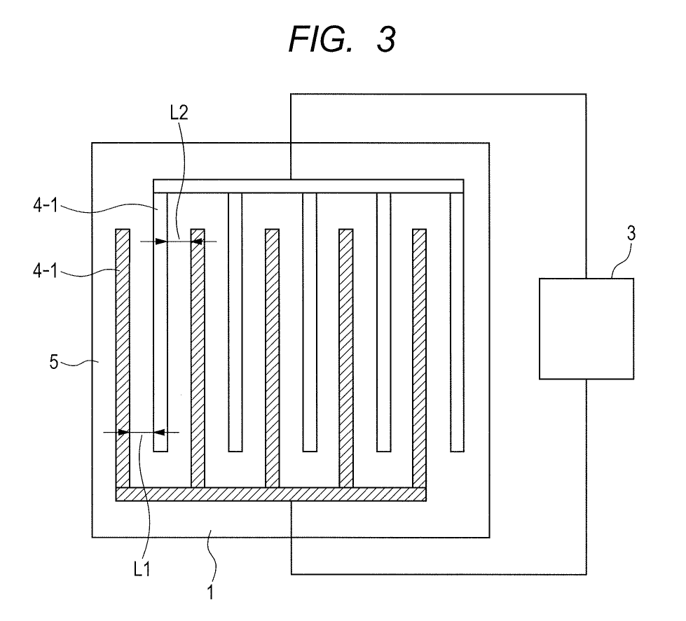

First, there is described a first embodiment of the invention with reference to FIGS. 1 to 4. FIG. 1 shows a general configuration of an atmospheric pressure plasma processing apparatus according to the first embodiment of the invention. This atmospheric pressure plasma processing apparatus is for use in forming an amorphous Si film, and a diamond like carbon (DLC) film on a plastic substrate, and a glass substrate, for example, 1 mm in thickness, 1 m in width, and 20 m in length, respectively. FIGS. 2A to 2C each are a schematic illustration showing a sectional structure of a part of the atmospheric pressure plasma processing apparatus, in the vicinity of a plasma discharge unit 1, and an operation thereof, respectively. FIG. 3 is a schematic sectional view (taken on line A-A′ of FIG. 2A) of the discharge unit of the atmospheric pressure plasma processing apparatus, as seen from above.

A plasma discharge unit 1 is installed inside an enclosure 16 in the ambient atmosphere. The plasma discharge unit 1 is substantially rectangular in planar shape. The enclosure 16 forms a processing chamber, the wall surface thereof being electrically grounded. There is formed a subject under-processing holding plane B-B′ for transferring, and holding a subject under-processing along a region where a plasma 6 is generated, on the surface of the plasma discharge unit 1, with the use of multiple rollers 17. The atmospheric pressure plasma processing apparatus is structured such that a side of a subject under-processing 7, adjacent to the back surface thereof, is held by the respective surfaces of the plural rollers 17, and the surface of the plasma discharge unit 1, and the subject under-processing 7 is caused to pass along the subject under-processing holding plane B-B′ over the plasma discharge unit 1 inside the enclosure 16. At this point in time, the subject under-processing 7 is transferred with the surface thereof, facing the plasma 6. Further, needless to say, it is to be pointed out that a unit for transferring the subject under-processing 7 is not limited to the rollers, and that use may be made of a belt, and other transfer unit.

A processing gas for use in plasma generation is supplied, via a shower head 8, to a portion of space, inside the enclosure 16, for plasma generation. The processing gas for use in plasma generation is supplied from a processing gas supply source 9-1 to the shower head 8 via a gas supply line 10-1. The processing gas for use in plasma generation is a gas diluted by a rare gas having the tendency toward electric discharge, such as helium, argon, and so forth. If a gap 23 exits between the plasma discharge unit 1, and the subject under-processing 7 (as described in detail later), a discharge-inhibition gas, such as nitrogen gas resistant to electric discharge, and so forth, is supplied from each of discharge-inhibition gas feeders 14 (14-1, 14-2, 1-3) installed at the respective ends of the plasma discharge unit 1. A discharge-inhibition gas is supplied from a gas supply source 9-2 to the gas feeders 14-1, 14-3 via gas lines 10-2, 10-4, respectively. Further, an exhaust system 11 is connected to the enclosure 16 via exhaust lines 12 (12-1, 12-2), respectively. Furthermore, a gas-atmosphere change-over device 13 is installed at an entry/delivery port for the subject under-processing, provided in the vicinity of the subject under-processing holding plane B-B′ of the enclosure 16.

As depicted in detail in FIG. 2A, and FIG. 3, the plasma discharge unit 1 includes a dielectric 5 having a flat surface, and electrodes 4 in pairs, coupled to a high-frequency power source 3 embedded in the dielectric 5. The electrodes 4 in pairs are structured such that two types of the electrodes 4-1, 4-2, serving as an antenna, and a ground, respectively, are alternately installed so as to be in parallel with each other. The electrodes 4-1, 4-2 are each coupled to the high-frequency power source 3 for plasma discharge. As shown in FIG. 2A, the dielectric 5 is made up such that a portion of a dielectric layer thereof, on a side adjacent to the discharge unit, for forming a plasma, is rendered smaller in thickness, and a thickness T1 of the portion is approximately from 10 μm to several mm. In contrast, a thickness T2 of a portion of the dielectric layer, on a side thereof, for forming no plasma, is not less than ten times as large as the thickness T1. In other words, the electrodes 4 in pairs are embedded unevenly in the dielectric in the direction of a thickness of the dielectric layer, in such a way so as to be disposed closer thicknesswise to the discharge unit than to the center of the dielectric layer. Further, the plasma discharge unit 1 is installed at a position where the surface of the dielectric, on a side of the plasma discharge unit, adjacent to the electric discharge, is effectively identical in height to the subject under-processing holding plane B-B′, that is, at a position in height, where the surface of the dielectric 5 comes into contact with, or effectively contacts the back surface of the subject under-processing 7. Herein, a symbol E indicates the diameter of the electrode 4. The two types of the electrodes 4-1, 4-2, serving as the antenna, and the ground, respectively, have an interval L provided therebetween, the interval L including an interval L1 between the electrode 4-1, and the electrode 4-2, and an interval L2 between the electrode 4-2, and the electrode 4-1.

The interval L (L1, L2) between the two types of the electrodes 4, serving as the antenna, and the ground, respectively, is preferably greater than the total of a thickness D of the subject under-processing 7, the thickness T1 of the dielectric surface layer, and a gap G occurring between the plasma discharge unit 1, and the subject under-processing 7. That is, if expression L>D+G+T holds, this is desirable. By so doing, if high-frequency electric power is impressed between the electrodes 4 in pairs, and an electric current is caused to flow therebetween, this is followed by occurrence of an electric force line 18, whereupon the electric force line 18 can sufficiently seep through toward a surface side of the subject under-processing 7, adjacent to a film-forming region.

This is further described hereinafter with reference to the respective schematic illustrations of FIGS. 2B and 2C. The subject under-processing 7 is comprised of a substrate part 7A, a SiN film to be deposited over the substrate part by making use of a plasma, and a thin film layer 7B such as a diamond-like carbon film, and so forth. FIG. 2B shows a state where the surface of the plasma discharge unit 1 effectively coincides with the subject under-processing holding plane B-B′, and the gap G between the surface of the plasma discharge unit 1, and the back surface of the subject under-processing 7 is zero (the subject under-processing 7 is in intimate contact with the plasma discharge unit 1 without a gap existing therebetween). The electric force line 18 occurs as a result of the high-frequency electric power being impressed between the electrodes 4 in pairs, and a portion of the electric force line 18 reaches the ambient atmosphere (a gas layer) inside the enclosure 16 via the dielectric 5 (a solid layer), and the subject under-processing 7 (a solid layer), whereupon an electric field of the electric force line 18 acts on the processing gas for use in plasma generation, thereby generating a plasma. That is, the electric field of intensity necessary for plasma generation can be formed simply by the agency of the ambient atmosphere in the vicinity of the surface side 22 of the subject under-processing 7, thereby generating the plasma 6.

Further, the gap G between the surface of the plasma discharge unit 1 and the back surface of the subject under-processing 7 is preferably zero (the subject under-processing 7 is in intimate contact with the plasma discharge unit 1 without the gap existing therebetween). However, there is also the case where the surface of the plasma discharge unit 1 need be kept apart by a miniscule distance from the subject under-processing holding plane B-B′ beforehand in order to effect smooth transfer of the subject under-processing 7, as shown in FIG. 2C, depending on the quality of the subject under-processing 7, the construction thereof, and so forth, whereupon the gap 23 minimal in size need be formed between the surface of the plasma discharge unit 1, and the back surface of the subject under-processing 7. However, the presence of the gap 23 as described will pose the risk of plasma generation caused by an electric field within the gap 23. In such a case, the discharge-inhibition gas, such as nitrogen gas resistant to electric discharge, and so forth, is supplied from each of the discharge-inhibition gas feeders 14 installed at the respective ends of the plasma discharge unit 1 to the gap 23 between the plasma discharge unit 1, and the subject under-processing 7. By so doing, if the gap G is not zero, electric discharge will not occur by the agency of nitrogen gas, however, through adjustment of a voltage of the high-frequency power from the power source 3 for plasma discharge such that electric discharge will occur by the agency of the processing gas diluted by the rare gas having the tendency toward electric discharge, a plasma can be generated by the agency of the ambient atmosphere only in the vicinity of the surface side 22 of the subject under-processing 7. More specifically, the electric force line 18 occurs as a result of the high-frequency electric power being impressed between the electrodes 4 in pairs, and a portion of the electric force line 18 reaches the ambient atmosphere (the gas layer) inside the enclosure 16 via the dielectric 5 (the solid layer), a discharge-inhibition gas layer, and the subject under-processing 7 (the solid layer), whereupon the electric field of the electric force line 18 acts on the processing gas for use in plasma generation, thereby generating a plasma.

Further, for a processing gas in forming an amorphous Si film, use is made of a gas based on a mixed gas of a rare gas, and an SiH₄ gas added thereto, with addition of hydrogen as necessary. In forming an SiN film, use is made of a processing gas obtained by diluting a mixed gas of SiH₄, H₂, and N₂, or ammonia, with a rare gas. In forming the diamond-like carbon film, use is preferably made of a gas obtained by adding hydrogen to a hydrocarbon gas, such as acetylene and so forth, as necessary, to be diluted by a rare gas.

With the first embodiment of the invention, while multiple the discharge-inhibition gas feeders 14 are provided, the discharge-inhibition gas feeders 14 are preferably controlled so as not to supply the discharge-inhibition gas if the subject under-processing 7 is not placed over any of the discharge-inhibition gas feeders 14. Further, multiple the plasma discharge units 1 maybe installed inside the enclosure 16, in which case, it is recommendable to stop electric discharge when the subject under-processing 7 is not over across the electric discharge plane of the plasma discharge units.

A gas atmosphere of the processing chamber (in the enclosure 16) substantially on the surface side of the subject under-processing is preferably the processing gas for use in film-formation, and a gas atmosphere on the back surface side of the subject under-processing is preferably a nitrogen gas. In this case, the gas atmosphere above the enclosure is exhausted by an exhaust system 11-1 comprised of a vacuum pump, and so forth, via an exhaust line 12-1, while the gas atmosphere below the enclosure is exhausted from an exhaust system 11-2 via an exhaust 12-2. Further, the gas collected by the exhaust system 11-1 may be supplied to the gas supply source 9-1, thereby enabling a portion of the gas to be circulated. Obviously, the gas collected by the exhaust system 11-2 may be supplied to the gas supply source 9-2, thereby enabling a portion of the gas to be circulated.

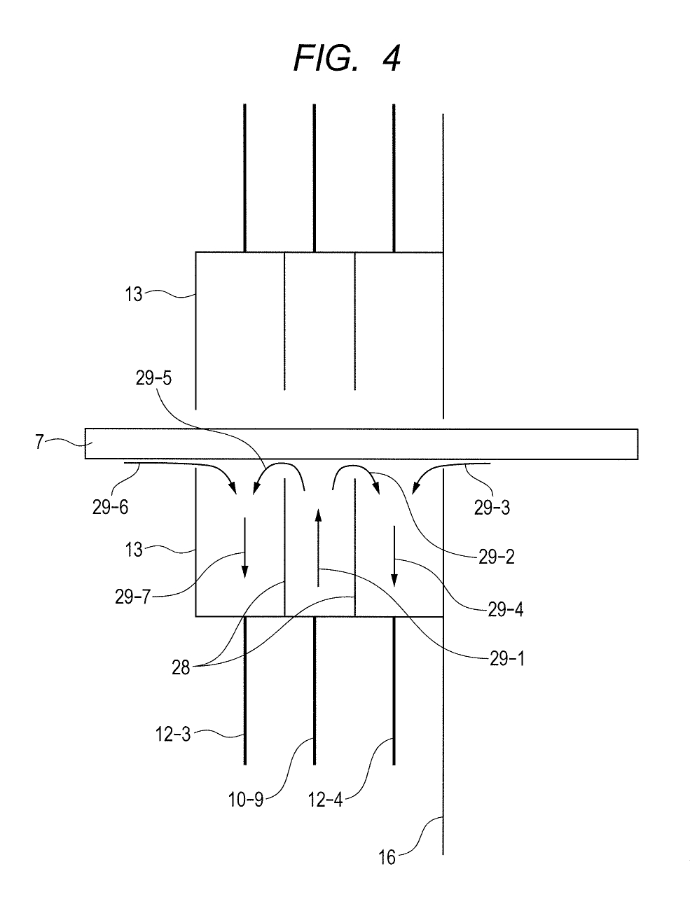

The gas-atmosphere change-over device 13 is installed at parts of the enclosure 16, for the entry/delivery of the subject under-processing. FIG. 4 is a schematic representation showing a construction of the gas-atmosphere change-over device 13 by way of example. The interior of the gas-atmosphere change-over device 13 is divided by partition plates 28 into three regions. A gas, such as a nitrogen gas, a rare gas, and so forth, are supplied to a center region via a gas supply line 10-9. The gas supplied to the center region flows into respective regions adjacent thereto, and a gas flow 29-2 is merged with a gas flow 29-3 flowing from the processing chamber to be turned into a gas flow 29-4, the gas flow 29-4 being subsequently exhausted via an exhaust line 12-4. Further, a gas 29-5 among the gases supplied from the gas supply line 10-9, flows to the gas-atmosphere change-over device 13, toward the left-side in the figure, and a gas flow 29-5 is merged with a gas flow 29-6 flowing from the ambient atmosphere to be turned into a gas flow 29-7, the gas flow 29-7 being subsequently exhausted via an exhaust line 12-3. By so doing, the ambient atmosphere is prevented from flowing into the processing chamber, that is, the enclosure 16. Further, if the pressure of an atmosphere (the ambient atmosphere) inside the enclosure 16 is defined as P1, and the pressure of the atmosphere is defined as P3, the following approximate relationship preferably holds:

P3<P3

More specifically, the plasma generated by the plasma discharge unit 1 is a plasma generated due to electric discharge occurring at the atmospheric-pressure, however, a pressure slightly lower than the atmosphere, that is, for example, 0.9 atm will do in the strict sense.

Thus, with the present embodiment of the invention, since a plasma is generated in the ambient atmosphere only in the vicinity of the surface of the subject under-processing, it is possible to inhibit film-formation on the plasma discharge unit 1, and the inner wall of a processing vessel. Accordingly, a cleaning cycle of the plasma processing apparatus can be prolonged, and productivity on a mass production basis can be enhanced.

### Second Embodiment

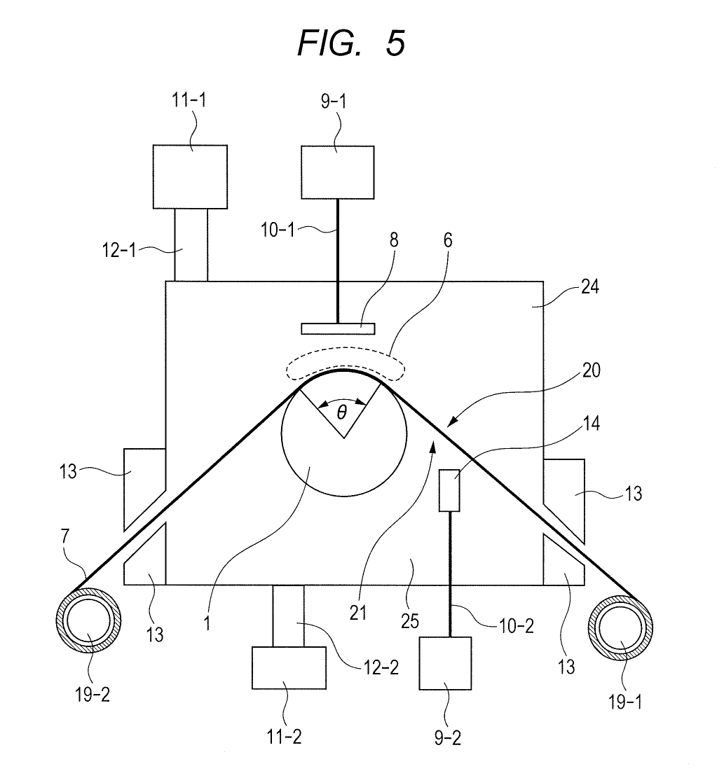

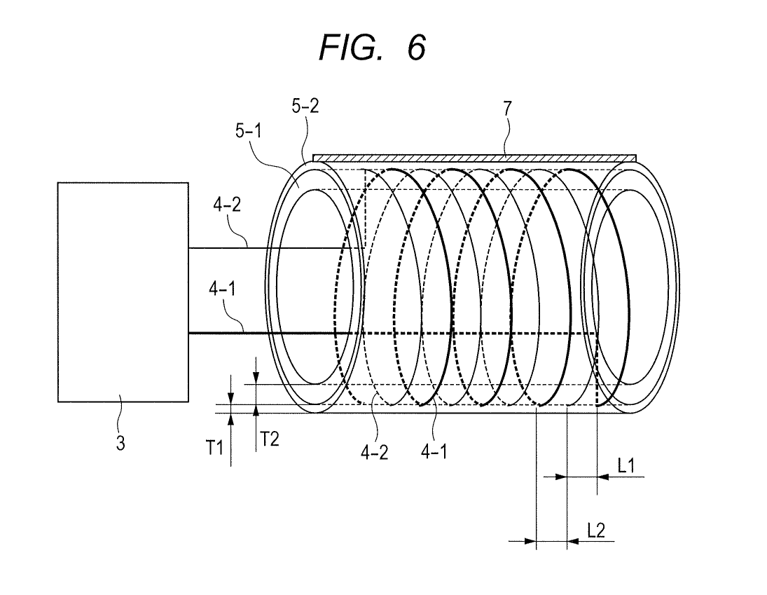

Next, a second embodiment of the invention is described hereinafter with reference to FIGS. 5, 6. Description on parts of a configuration according to the second embodiment, equivalent to those of the first embodiment, is omitted. With the present embodiment, there is broadly shown a configuration of an atmospheric pressure plasma processing apparatus of a Roll-to-Roll type compatible with a flexible substrate. A plasma source 1 capable of generating a plasma on the outer periphery of a cylinder is installed in an enclosure 16. In the processing system, a subject under-processing 7 is supplied from a roll 19-1 to be taken up by a roll 19-2. And the processing system is made up such that the subject under-processing 7 is kept in contact with a cylindrical plasma-discharge unit 1 across only a distance corresponding to an angle θ.

The structure of the plasma source 1 has an electrode structure shown in FIG. 6. A cylinder type discharge plasma source shown in FIG. 6 is structured such that two lengths of electrodes (lead wires) 4-1, 4-2, in parallel with each other, are spirally wound around on the surface of a cylindrical dielectric (an insulator) 5-1, and a dielectric layer 5-2, made of glass, alumina, yttria and so forth, is formed thereon. The electrodes (lead wires) 4-1 and 4-2 are coupled to a high-frequency power source 3. With this plasma discharge unit, a thickness T1 of the dielectric layer, corresponding to an inner side portion of a cylinder, as seen from the electrode 4, is, for example, not less than ten times as large as a thickness T2 of the dielectric layer, on the outer peripheral side of the cylinder, as seen from the electrode 4. Further, an interval L1 between the two lengths of the electrodes is substantially equivalent to an interval L2 between the electrodes when the electrodes are spirally wound around. If a thickness of the subject under-processing 7 is defined as D, and a gap occurring between the subject under-processing 7 and a discharge unit is defined as G, the following relationship is preferable:

L1≈L2>D+G+T2

Needless to say, G at nearly 0 mm is preferable.

A processing gas supplied from a processing gas supply system 9-1 is supplied via a gas supply line 10-1, and a shower head 8 to the surface side 20 of the subject under-processing 7, that is, a space 24 in contact with a plane on which a processing for film-formation is carried out. For the processing gas, use is made of the gas diluted by the rare gas, as is the case with the first embodiment. A gas more resistant to electric discharge than the processing gas, such as a nitrogen gas, is supplied to a space 25 in contact with the back side 21 of the subject under-processing 7 from a gas supply source 9-2 via a gas supply line 10-2 through a gas supply port 14. By so doing, a plasma 6 is generated on the surface side of the subject under-processing 7 in contact with the plasma source 1 while no plasma is generated on a side of the subject under-processing 7, out of contact with the plasma source 1 (a lower side part in the figure). Further, a gas-atmosphere change-over device 13 is installed at a subject under-processing entry/delivery port of the enclosure 16 in order to prevent the atmosphere from entering the enclosure serving as a processing chamber. If the pressure of the space 24 (the ambient atmosphere) on a plasma-generating side is defined as P1, the pressure of the space 25 on a side of the subject under-processing 7, for generating no plasma, is defined as P2, and the pressure of the atmosphere around the enclosure is defined as P3, the following relationship is preferably set up so as to cause a slight difference in pressure therebetween:

P1<P2<P3

For this reason, an exhaust system 11-1 comprised of a vacuum pump, and so forth, is connected to the space 24 on the plasma-generating side of the enclosure, via an exhaust line 12-1. Further, an exhaust system 11-2 is connected to the space 25 on the side of the subject under-processing 7, for generating no plasma, via an exhaust duct 12-2.

With the present embodiment as well, since a plasma is generated in the ambient atmosphere only in the vicinity of the surface of the subject under-processing, it is possible to inhibit film-formation on the plasma discharge unit, and the inner wall of a processing vessel. Accordingly, a cleaning cycle of the plasma processing apparatus can be prolonged, and productivity on a mass production basis can be enhanced.

### First Modification

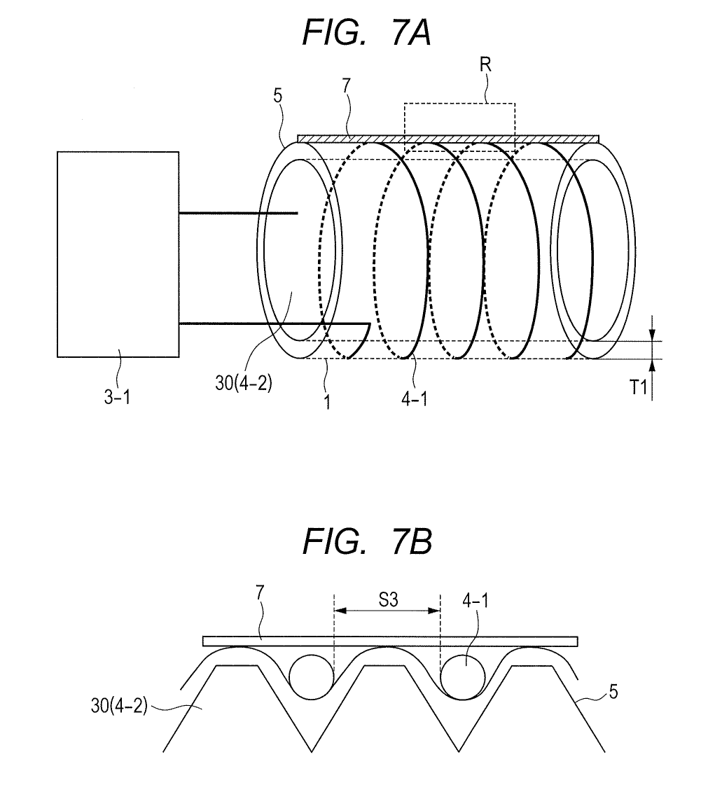

Now, a first modification of the second embodiment of the invention is described hereinafter with reference to FIG. 7 (FIGS. 7A, 7B). A plasma discharge unit shown in FIG. 7A is structured such that a dielectric layer 5 made of yttria, alumina, and so forth is formed on the outer periphery of a metal cylinder 30 equivalent to the electrode 4-2, and an electrode (a lead wire) 4-1 is spirally wound around on the outer periphery of the dielectric layer 5. FIG. 7B is an enlarged sectional view showing a construction of a part R of FIG. 7A by way of example. If a spiral groove (screw groove) is provided on the surface of the metal cylinder 30, the dielectric layer 5 is formed over the spiral groove, and the electrode 4-1 is wound around along the groove exposed on the dielectric layer, this will provide the merit of simplification in manufacturing. Further, if a pitch of the electrode 4-1 is defined as S3, the following relationship preferably holds:

1/2×S3>D+G

With the present embodiment as well, since a plasma is generated in the ambient atmosphere only in the vicinity of the surface of the subject under-processing, it is possible to inhibit film-formation on the plasma discharge unit, and the inner wall of a processing vessel. Accordingly, a cleaning cycle of the plasma processing apparatus can be prolonged, and productivity on a mass production basis can be enhanced.

### Third Embodiment

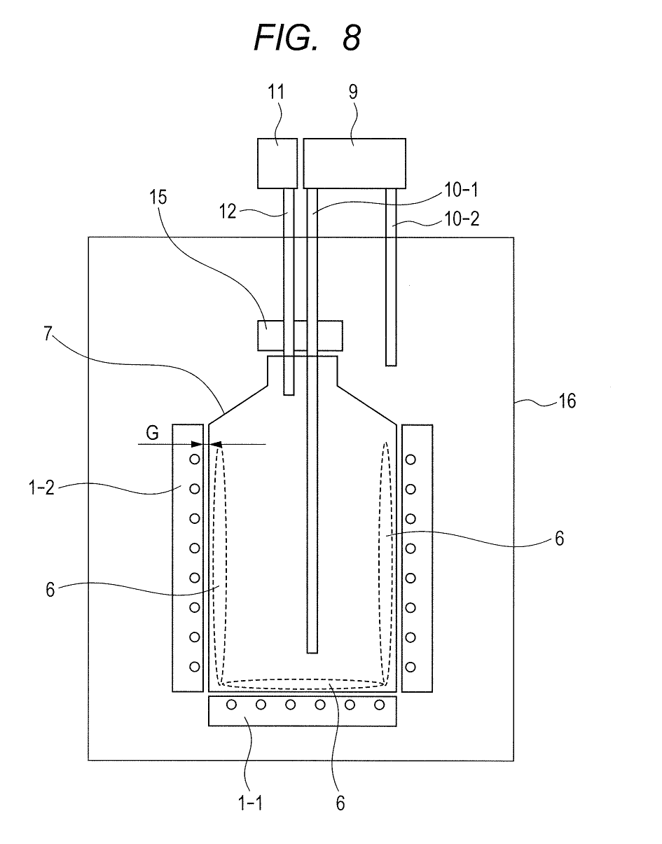

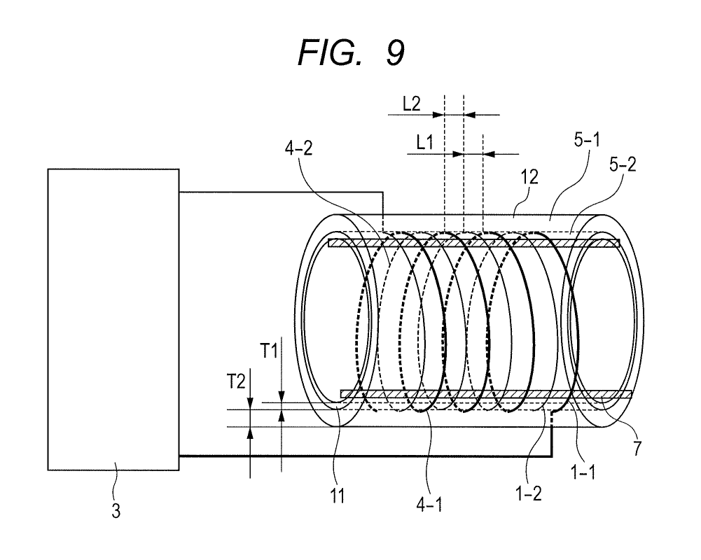

Next, a third embodiment of the invention is described hereinafter with reference to FIGS. 8, 9. Description on parts of a configuration in the figures, equivalent to those of the first embodiment, or the second embodiment, is omitted. With the present embodiment, there is broadly shown a system for applying a plasma processing to a surface of a receding part such as the interior of a vessel, and so forth. Plasma discharge units 1-1, 1-2 are installed inside an enclosure 16. The plasma discharge unit 1-1 is a flat-plate type plasma source of a construction equivalent to that according to the first embodiment, and is installed on a planar portion of the wall surface of a processing object such as, for example, the bottom of a vessel. The plasma discharge unit 1-2 is to generate a plasma on the inner side of a cylinder, having an electrode construction shown in, for example, in FIG. 9. With the present embodiment, a vessel 7 as a subject under-processing is held in a holding-space part provided on the inner sides of the plasma discharge units 1-1, 1-2, respectively. The vessel as the subject under-processing is brought into the holding-space part by, for example, a transport robot to be then sent out after a plasma processing

With an electric discharge plasma source on the inner periphery of a cylinder, shown in FIG. 9, dielectric barrier discharge electrodes 4-1, 4-2, in pairs are in a spirally-wound state to be confined inside a dielectric 5. The electrodes 4-1, 4-2 are coupled to a high-frequency power source 3 for plasma generation.

A thickness T1 of a dielectric 5-2 of the dielectric 5, corresponding to an inner side portion of the cylinder, as seen from the electrode 4, is, for example, not less than ten times as large as a thickness T2 of a dielectric 5-1 on the outer side of the dielectric 5, as seen from the electrode 4. By so doing, a plasma is generated in an inner side portion of the cylinder.

As for dimensions of a distance between the vessel and the plasma source, and so forth, in the case of using the plasma source shown in FIG. 9, a relationship among a thickness D of the wall face of the subject under-processing 7 (the vessel), a distance G between the plasma source and the vessel, a thickness T1 of a dielectric layer, and electrode intervals L1, L2 is preferably represented by the following inequality:

L1≈L2>D+G+T1

If the electrode interval L1 differs in value from the electrode interval L2, the inequality as above preferably holds against whichever electrode lower in value, that is, the electrode interval L1, or the electrode interval L2.

By so doing, the vessel as the subject under-processing can be brought into the holding-space part, and a plasma can be generated on the inner wall surface of the vessel, so that a plasma processing can be applied to the interior of the vessel. Further, with the present embodiment as well, since a plasma is generated in the ambient atmosphere only in the vicinity of the surface of the subject under-processing, in other words, only inside the vessel, it is possible to inhibit film-formation on the plasma discharge unit, and the inner wall of a processing system. Accordingly, a cleaning cycle of a plasma processing apparatus can be prolonged, and productivity on a mass production basis can be enhanced.

### Second Modification

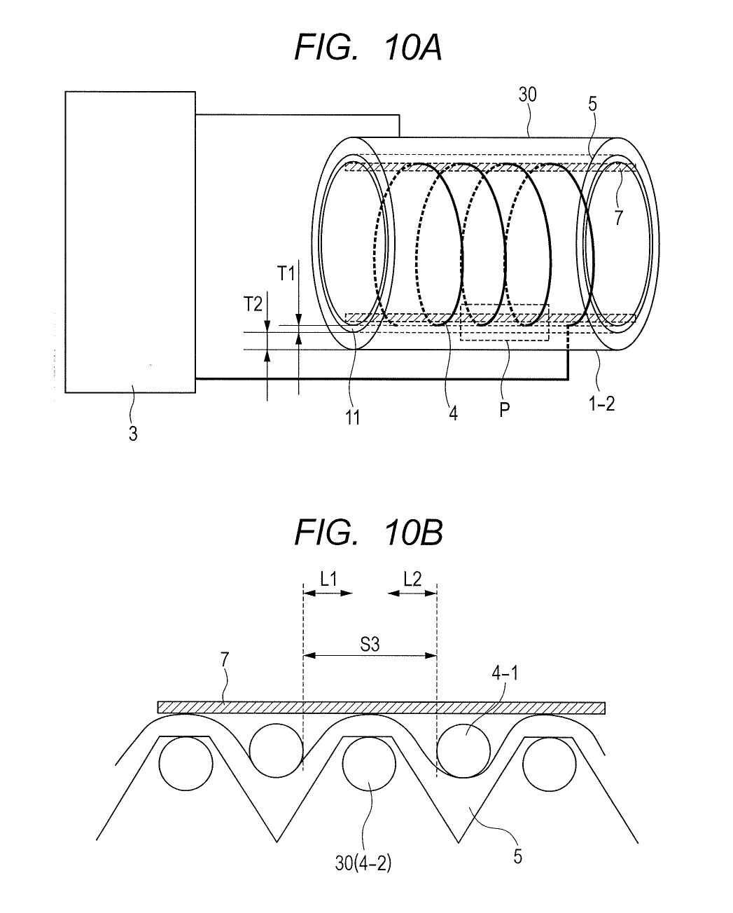

Next, a second modification of the third embodiment of the invention is described hereinafter with reference to FIG. 10 (FIGS. 10A, 10B).

With a discharge plasma source on the inner periphery of a cylinder, shown in FIG. 10A, a dielectric layer 5 is formed on the inner side of a cylindrical component 30 made of metal, and an electrode 4 is spirally provided on the inner side of the dielectric layer 5. Further, FIG. 10B shows the construction a part P of FIG. 10A by way of example. In the example of FIG. 10B, a screw groove is formed on the inner side surface of the cylindrical component 30 made of metal, and subsequently, the dielectric layer 5 is formed, thereby rendering it possible to install the electrode 4 at equal intervals with ease.

A gas line 10-1 for use in supplying a processing gas, and a gas line 12 for exhausting a gas inside the vessel are provided in the vessel. Further, the vessel is provided with a lid 15 for preventing the processing gas in the vessel from being diffused within the enclosure 16. For the processing gas, use is made of the gas diluted by the rare gas as is the case with the first embodiment. Further, in the case of carrying out sterilization, use is made of a mixed gas obtained by diluting, for example, an oxygen gas by a rare gas. A gas resistant to electric discharge as compared with the processing gas, such as a nitrogen gas, is supplied via a gas line 10-2 to a space inside the enclosure 16, but outside the vessel.

In the case of using a plasma source shown in FIG. 10A, if a pitch of the electrode in FIG. 10B is defined as S3 (L3≈L1+L2, L1=L2), the following relationship preferably holds:

1/2×S3>D+G

As a result, a plasma is generated on the inner wall surface of the vessel as the subject under-processing 7, and a plasma processing can be applied to the interior of the vessel.

The embodiments described above assume that plasma processes are conducted in almost atmospheric pressure condition. However, the present invention, of course, can be applied to plasma processes which are conducted in decompressed conditions.

1. A plasma processing apparatus comprising:
a plasma discharge unit in an ambient atmosphere, installed inside a processing chamber;
a high-frequency power source configured to supply high-frequency power to the plasma discharge unit;
a processing gas supply source configured to supply a processing gas to the processing chamber; and
a subject under-processing holding unit configured to hold the back surface of a subject under-processing,
wherein the plasma discharge unit is a plasma source of the dielectric barrier discharge mode of an surface discharge type, incorporating electrodes in pairs, disposed in parallel with each other inside a dielectric, thereby generating a plasma on a surface of the dielectric, the subject under-processing is held by a predetermined subject under-processing holding plane in the plasma discharge unit, the surface of the dielectric, and the subject under-processing holding plane are effectively at the same level in the plasma discharge unit, thereby enabling the plasma to be generated in the ambient atmosphere in the vicinity of a surface of the subject under-processing, on a side thereof, opposite from the subject under-processing holding plane.

2. The plasma processing apparatus according to claim 1, wherein a gap G between a surface of the plasma discharge unit, and the subject under-processing holding plane is zero, and the processing gas diluted by a rare gas is supplied to a plane on a side of the subject under-processing, for plasma generation.

3. The plasma processing apparatus according to claim 1, wherein a miniscule gap exits between a surface of the plasma discharge unit and the back surface of the subject under-processing held by the subject under-processing holding plane, and a discharge-inhibition gas feeder for supplying a discharge-inhibition gas is provided in the miniscule gap.

4. The plasma processing apparatus according to claim 3, wherein the processing gas diluted by a rare gas is supplied to a plane on a side of the subject under-processing, for plasma generation, and the discharge-inhibition gas more resistant to electric discharge than the processing gas is supplied to a plane on a side of the subject under-processing, where the plasma source is provided.

5. The plasma processing apparatus according to claim 1, wherein the plasma discharge unit is substantially rectangular in planar shape, the electrodes in pairs are embedded unevenly in the dielectric in the direction of a thickness of a layer of the dielectric in such a way so as to be disposed closer thicknesswise to a side of the dielectric, adjacent to the surface thereof, than to the center of the layer of the dielectric, and a plurality of rollers for use in transferring the subject under-processing along the subject under-processing holding plane that is in parallel with the surface of the plasma discharge unit are provided.

6. A plasma processing apparatus comprising:
a plasma discharge unit in an ambient atmosphere, installed inside a processing chamber;
a high-frequency power source configured to supply high-frequency power to the plasma discharge unit;
a processing gas supply source configured to supply a processing gas to the processing chamber; and
a subject under-processing holding unit configured to hold the back surface of a subject under-processing,
wherein the plasma discharge unit is a plasma source of the dielectric barrier discharge mode of an surface discharge type, incorporating one electrode of electrodes in pairs, disposed in a cylindrical dielectric, thereby generating a plasma on a surface of the cylindrical dielectric, the subject under-processing is disposed in such a way as to be substantially in contact with the plasma source, and the plasma is generated on a plane on a side of the subject under-processing, opposite from a plane where the plasma source is disposed.

7. The plasma processing apparatus according to claim 6, wherein the plasma discharge unit is structured such a layer of the dielectric is disposed on the outer periphery of a metal cylindrical component equivalent to the one electrode of the electrodes in pairs, and the other of the electrodes in pairs is spirally wound around on the outer periphery of the layer of the dielectric.

8. The plasma processing apparatus according to claim 6, wherein the plasma discharge unit is structured such a layer of the dielectric is disposed on the inner side of a metal cylindrical component equivalent to the one electrode of the electrodes in pairs, and the other of the electrodes in pairs is spirally wound around on the inner side of the layer of the dielectric.

9. (canceled)

10. (canceled)
